(19) United States
(12) Patent Application Publication
(10) Pub. No.: US 2011/0048530 A1
(43) Pub. Date: Mar. 3, 2011

(54) SURFACE NUCLEATED GLASSES FOR PHOTOVOLTAIC DEVICES

(76) Inventor: Sasha Marjanovic, Painted Post, NY (US)

(21) Appl. No.: 12/868,953

(22) Filed: Aug. 26, 2010

Related U.S. Application Data
(60) Provisional application No. 61/238,398, filed on Aug. 31, 2009.

(51) Int. Cl. H01L 31/04

(52) U.S. Cl. 136/256; 136/252; 136/260; 136/262; 136/258; 136/261

(57) ABSTRACT

Surface nucleated glass ceramics and more particularly photovoltaic devices comprising surface nucleated glass ceramics as the superstrate in the devices are described.

This application claims the benefit of priority to U.S. Provisional Application 61/238,398 filed on Aug. 31, 2009.

### BACKGROUND

1. Field

Embodiments relate to surface nucleated glass ceramics and more particularly to surface nucleated glass ceramics useful for, for example, photovoltaic devices.

2. Technical Background

Surface crystallization or surface nucleation methods for glass strengthening were invented in Corning Incorporated by Stanley D. Stookey in the late nineteen fifties. Later, the idea of glass strengthening by developing a surface crystalline layer was spread and studied through both academic and industrial communities.

Additional work by Corning Incorporated continued. The goals of the work mentioned were glasses that would be strengthened by developing a surface crystalline layer, while remaining transparent. Interestingly, some compositions that contained TiO₂ resulted in the creation of colored glassware.

Typically when making surface crystallized glass ceramics such as lithium alumina-silicates, the glasses are melted and formed in a conventional way. Later, they are heat treated to promote surface crystallization. With controlled heat treatments, the glass can remain pristine below the surface, while overall glass transparency depends on the thickness of the crystalline layer. Further, the glass ceramics can be fully crystalline. Compressive stresses are generated at the glass ceramic surface upon cooling, therefore making strong glass ceramics, sometimes in excess of 700 MPa of flexural strength. There are some challenges associated with the process. For example, high temperature heat treatments are needed, deformation is common, transparency is quite challenged, and fundamental understanding of the process itself is still not complete.

For thin-film photovoltaic cells such as silicon thin-film photovoltaic cells light advantageously is effectively coupled into the silicon layer and subsequently trapped in the layer to provide sufficient path length for light absorption. A light path length greater than the thickness of the silicon is especially advantageous.

A typical tandem cell incorporating both amorphous and microcrystalline silicon typically has a substrate having a transparent electrode deposited thereon, a top cell of amorphous silicon, a bottom cell of microcrystalline silicon, and a back contact or counter electrode. Light is typically incident from the side of the deposition substrate such that the substrate becomes a superstrate in the cell configuration.

Amorphous silicon absorbs primarily in the visible portion of the spectrum below 700 nanometers (nm) while microcrystalline silicon absorbs similarly to bulk crystalline silicon with a gradual reduction in absorption extending to about 1200 nm. Both types of material can benefit from surfaces having enhanced scattering, trapping, and/or improved transmission.

Textured TCOs have been developed to enhance scattering, trapping, and/or improve transmission. Disadvantages with textured TCO technology can include one or more of the following: 1) excessive roughness degrades the quality of the deposited silicon and creates electrical shorts such that the overall performance of the solar cell is degraded; 2) texture optimization is limited both by the textures available from the deposition or etching process and the decrease in transmission associated with a thicker TCO layer; and 3) plasma treatment or wet etching to create texture adds manufacturing cost in the case of ZnO.

Textured glass superstrates or substrates have been developed to enhance scattering, trapping, and/or improve transmission. Disadvantages with the textured glass substrate approach can include one or more of the following: 1) sol-gel chemistry and associated processing is required to provide binding of glass microspheres to the substrate; 2) additional costs associated with silica microspheres and sol-gel materials; and 3) problems of film adhesion and/or creation of cracks in the silicon film.

It would be advantageous to have superstrates for thin-film photovoltaic devices which could enhance scattering, trapping, and/or improve transmission within the photovoltaic device.

### SUMMARY

Superstrates for thin-film photovoltaic devices as described herein, address one or more of the above-mentioned disadvantages of the conventional light scattering or trapping structures.

One embodiment is a photovoltaic device comprising a glass ceramic superstrate comprising a surface nucleated surface layer, and having a first surface and a second surface opposite the first surface, a conductive film adjacent to the glass ceramic substrate, and an active photovoltaic medium adjacent to the conductive film.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework to understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawings.

FIG. 1 is an illustration of a photovoltaic device according to one embodiment.

FIG. 2 is an illustration of a photovoltaic device according to one embodiment.

FIG. 3A is a cross sectional scanning electron microscope (SEM) image of a glass ceramic superstrate, according to one embodiment.

FIG. 3B is a top view down scanning electron microscope (SEM) image of the surface nucleated surface layer glass ceramic superstrate, according to one embodiment.

FIG. 4 is a plot of the angular scattering of exemplary glass ceramic 1 from Table 1.

FIG. 5 is a transmittance spectral plot of exemplary glass ceramic 1 from Table 1.

FIG. 6 is a reflectance spectral plot of exemplary glass ceramic 1 from Table 1.

FIG. 7 is a transmittance spectral plot showing total and diffuse transmittance vs. wavelength of an exemplary superstrate.

FIG. 8 is a plot of the angular scattering of an exemplary superstrate.

FIG. 9 is a plot of total integrated scattering vs. large angle scattering for an exemplary superstrate.

FIG. 10 is a transmittance spectral plot showing total and diffuse transmittance vs. wavelength of an exemplary superstrate.

FIG. 11 is a plot of the angular scattering of an exemplary superstrate.

FIG. 12 is a plot of total integrated scattering vs. large angle scattering for an exemplary superstrate.

### DETAILED DESCRIPTION

Reference will now be made in detail to various embodiments of the invention, an example of which is illustrated in the accompanying drawings.

As used herein, the term “volumetric scattering” can be defined as the effect on paths of light created by inhomogeneities in the refractive index of the materials that the light travels through.

As used herein, the term “surface scattering” can be defined as the effect on paths of light created by interface roughness between layers in a photovoltaic cell.

As used herein, the term “superstrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

As used herein, the term “planar” can be defined as having a substantially topographically flat surface.

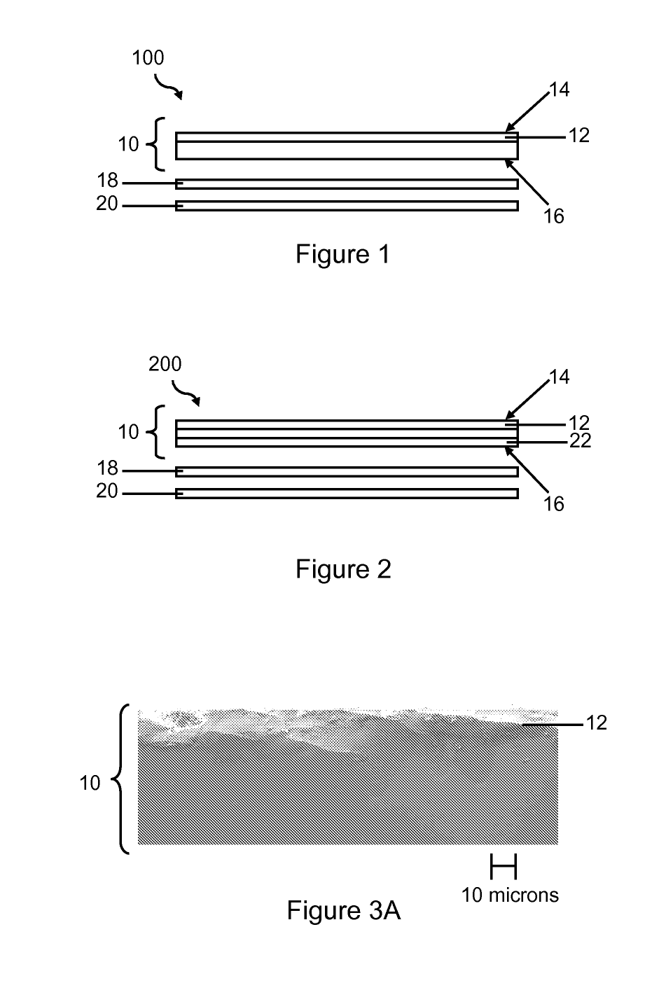

One embodiment as shown in FIG. 1 is a photovoltaic device 100 comprising a glass ceramic superstrate 10 comprising a surface nucleated surface layer 12, and having a first surface 14 and a second surface 16 opposite the first surface, a conductive film 18 adjacent to the glass ceramic substrate, and an active photovoltaic medium 20 adjacent to the conductive film.

According to one embodiment, the conductive film is disposed on the first surface. In another embodiment, the conductive film is disposed on the second surface.

The active photovoltaic medium, in one embodiment, is in physical contact with the conductive film.

The device, according to one embodiment, further comprises a counter electrode in physical contact with the active photovoltaic medium and located on an opposite surface of the active photovoltaic medium as the conductive film. The active photovoltaic medium can comprise multiple layers. The active photovoltaic medium, in some embodiments, comprises cadmium telluride, copper indium gallium diselenide, amorphous silicon, crystalline silicon, microcrystalline silicon, or combinations thereof.

In one embodiment, the surface nucleated layer has an average thickness of from 30 microns to 150 microns.

As shown in FIG. 2, the device, according to some embodiments, comprises two or more surface nucleated surface layers 12 and 22.

Also shown in FIG. 2, the device according to one embodiment, the glass ceramic superstrate comprises two surface nucleated surface layers, one 12 located at the first surface 14 and another 22 located at the second surface 16.

The glass ceramic superstrate, in one embodiment, comprises a zinc doped lithium alumina silicate.

High material strength is advantageous for photovoltaic cells. Surface nucleated glass ceramics offer strength almost similar to those achieved by ion exchange, but at much lower cost. If needed, these glass ceramics can be ion exchanged for additional strength improvement. In some embodiments, the glass ceramic superstrate is ion exchanged.

According to one embodiment, the glass ceramic is ion exchanged in a salt bath comprising one or more salts of alkali ions. The glass ceramic can be ion exchanged to change its mechanical properties. For example, smaller alkali ions, such as lithium or sodium, can be ion-exchanged in a molten salt containing one or more larger alkali ions, such as sodium, potassium, rubidium or cesium. If performed at a temperature well below the strain point for sufficient time, a diffusion profile will form in which the larger alkali moves into the glass ceramic surface from the salt bath, and the smaller ion is moved from the interior of the glass ceramic into the salt bath. When the sample is removed, the surface will go under compression, producing enhanced toughness against damage. Such toughness may be desirable in instances where the glass ceramic will be exposed to adverse environmental conditions, such as photovoltaic grids exposed to hail. A large alkali already in the glass ceramic can also be exchanged for a smaller alkali in a salt bath. If this is performed at temperatures close to the strain point, and if the glass is removed and its surface rapidly reheated to high temperature and rapidly cooled, the surface of the glass ceramic will show considerable compressive stress introduced by thermal tempering. This will also provide protection against adverse environmental conditions. It will be clear to one skilled in the art that any monovalent cation can be exchanged for alkalis already in the glass ceramic, including copper, silver, thallium, etc., and these also provide attributes of potential value to end uses, such as introducing color for lighting or a layer of elevated refractive index for light trapping.

In one embodiment, the superstrate is planar. The first surface and/or the second surface is substantially topographically flat, in one embodiment. In another embodiment, both surfaces are substantially topographically flat.

The conductive film, according to one embodiment, is transparent. The conductive film can comprise a textured surface. The conductive film can be transparent and comprise a textured surface.

The glass ceramic superstrate comprising a surface nucleated surface layer as described herein can be used to scatter light coming into the photovoltaic cell and backscatter the light reflected from silicon surface. This may improve photovoltaic cell efficiency.

The surface nucleated layer, in one embodiment, comprises glass ceramics comprising lithium alumina-silicate compositions, which have high strength after heat treatment, since compressive stresses are generated by the crystals at the glass ceramic surface upon their cooling. In one embodiment, the composition is doped with fluorine, chlorine, zinc, or combinations thereof. The composition, in one embodiment, comprises in mole percent: 60 to 70 SiO₂, 10 to 20 Al₂O₃, and 5 to 15 Li₂O. The composition can further comprise greater than 0 to 20 percent RO, wherein R is an alkaline earth metal. In one embodiment, R is Ca, Mg, or a combination thereof. In one embodiment, the composition further comprises greater than 0 to 10 percent M₂O, wherein M is an alkali metal. According to one embodiment, M is Na. Exemplary compositions in mole percent are found in Table 1.

TABLE 1

| Oxide | 1 | 2 | 3 | 4 | 5 | 6 | 7 | 8 | 9 | 10 |
|---|---|---|---|---|---|---|---|---|---|---|
| SiO₂ | 62.23 | 62.2 | 65.36 | 64.13 | 67.82 | 68.82 | 62.23 | 62.23 | 62.23 | 62.23 |
| Al₂O₃ | 13.18 | 16.3 | 15.10 | 16.20 | 15.49 | 14.38 | 13.18 | 13.18 | 13.18 | 13.18 |
| Li₂O | 6.84 | 14.6 | 13.31 | 13.25 | 12.33 | 12.44 | 6.84 | 6.84 | 6.84 | 6.84 |
| ZnO | 5.61 | 3.46 | 4.7 | 3.27 | 3.41 | 3.41 | 5.61 | 5.61 | 5.61 | 4.61 |
| MgO | 12.14 | 0 | 0 | 0 | 0 | 0 | 12.14 | 12.14 | 12.14 | 11.14 |
| CaO | 0 | 2.83 | 0 | 1.69 | 0.1 | 0.1 | 0 | 0 | 0 | 0 |
| Na₂O | 0 | 0.61 | 1.53 | 1.01 | 0 | 0 | 0 | 0 | 0 | 0 |
| B₂O₃ | 0 | 0 | 0 | 0.45 | 0.85 | 0.85 | 0 | 0 | 0 | 0 |
| F⁻ | 0 | 0 | 0 | 0 | 0 | 0 | 2 | 0 | 1 | 0 |
| Cl⁻ | 0 | 0 | 0 | 0 | 0 | 0 | 0 | 2 | 1 | 1 |

The temperature and the length of the heat treatments can control the overall transparency, which depends on the thickness of the grown crystalline layer, while glass remains pristine bellow the crystallized surface. The size of the crystals grown at the glass surface and the thickness of such crystal layer can manipulate and scatter the incoming light, as well as to backscatter the light reflected from silicon surface. This should significantly improve photovoltaic cell efficiency.

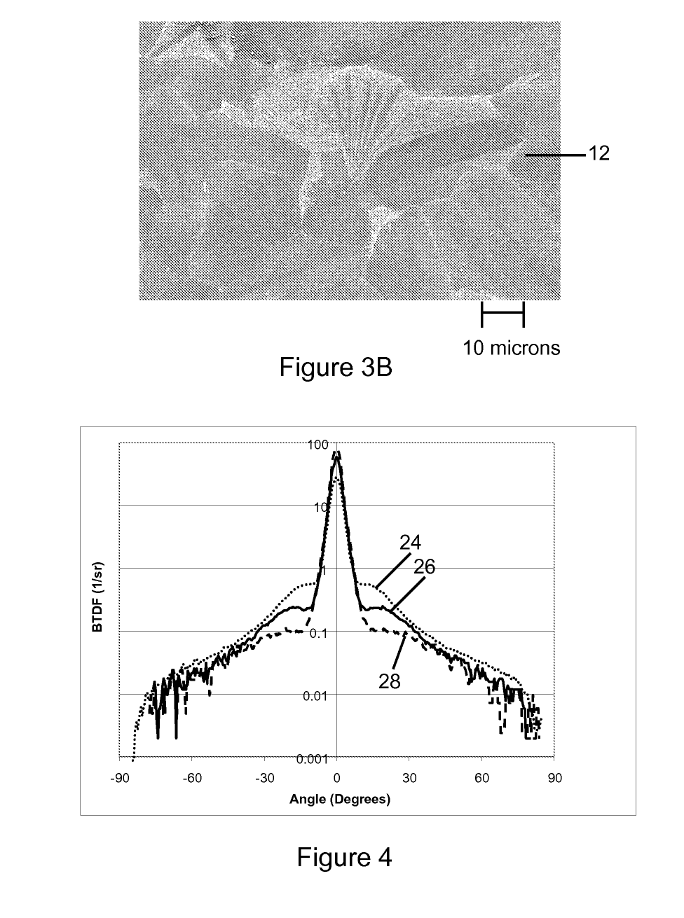

A cross sectional scanning electron microscope (SEM) image of a glass ceramic superstrate 10 comprising a surface nucleated surface layer 12, according to one embodiment is shown in FIG. 3A.

A top view down scanning electron microscope (SEM) image of the surface nucleated surface layer 12, according to one embodiment is shown in FIG. 3B.

In both FIG. 3A and FIG. 3B the surface nucleated surface layer shown was after 4 hrs heat treatment at 800° C. of exemplary glass ceramic 1 from Table 1.

A plot of the angular scattering of exemplary glass ceramic 1 from Table 1 is shown in FIG. 4. Lines 24, 26, and 28 show angular scattering at 450 nm, 600 nm, and 800 nm respectively. A broad angular scattering that decreases in strength with wavelength and a broadened small angle peak that is constant with wavelength suggest the combination of the volumetric scattering and the surface scattering on the sample. It appears that the surface has two periodicities: one, very small, on the order of a micron and the other, larger, on the order of 10 microns.

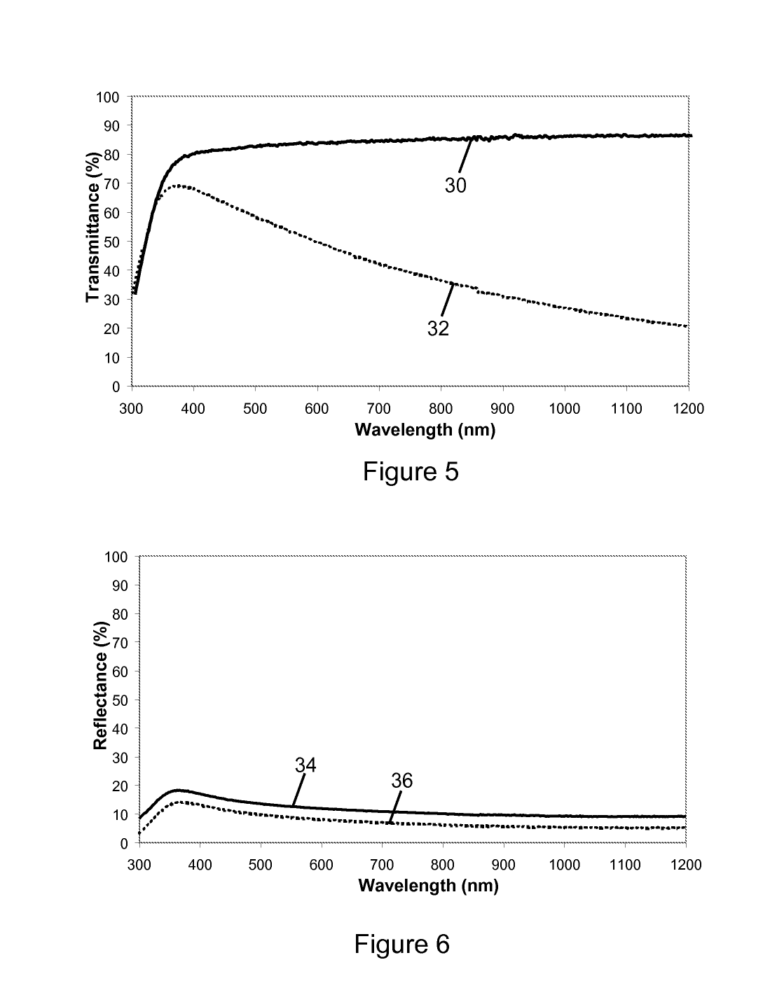

FIG. 5 is a transmittance spectral plot of exemplary glass ceramic 1 from Table 1. Line 30 and line 32 show total transmittance and diffuse transmittance respectively. The glass ceramic shows good total transmittance of more than 80 percent in the wavelength range from 400 nm to 1200 nm.

FIG. 6 is a reflectance spectral plot of exemplary glass ceramic 1 from Table 1. Line 34 and line 36 show total transmittance and diffuse transmittance respectively. The glass ceramic shows a low total reflectance of less than about 15 percent in the wavelength range from 400 nm to 1200 nm.

The glass ceramic superstrate can be used to manipulate the scattering of light from the surface nucleated surface layer. Crystals of various sizes within the surface nucleated surface layer and various layer thicknesses can be used to affect the light scattering and/or trapping properties of the photovoltaic device.

In one embodiment, the average thickness of the superstrate is 3.2 millimeters (mm) or less, for example, from 0.7 millimeters to 1.8 millimeters. In one embodiment, the surface nucleated layer has an average thickness of 250 microns or less, for example, greater than zero to 250 microns, for example, from 10 microns to 250 microns, for example, from 15 microns (μm) to 250 microns. In one embodiment, the surface nucleated layer has an average thickness of 150 microns or less, for example, greater than zero to 150 microns, for example, from 10 microns to 150 microns, for example, from 15 microns (μm) to 150 microns.

In one embodiment, the surface nucleated layers when there is more than one present have a total average thickness of 250 microns or less, for example, greater than zero to 250 microns, for example, from 10 microns to 250 microns, for example, from 15 microns (μm) to 250 microns. In one embodiment, the surface nucleated layers have an average thickness of 150 microns or less, for example, greater than zero to 150 microns, for example, from 10 microns to 150 microns, for example, from 15 microns (μm) to 150 microns.

In one embodiment, the superstrate is not fully crystalline. In another embodiment, the superstrate is 90 percent crystalline or less, for example, greater than zero percent to 90 percent crystalline. There is a layer of amorphous glass. In some embodiments, there are two surface nucleated surface layers sandwiching the amorphous glass.

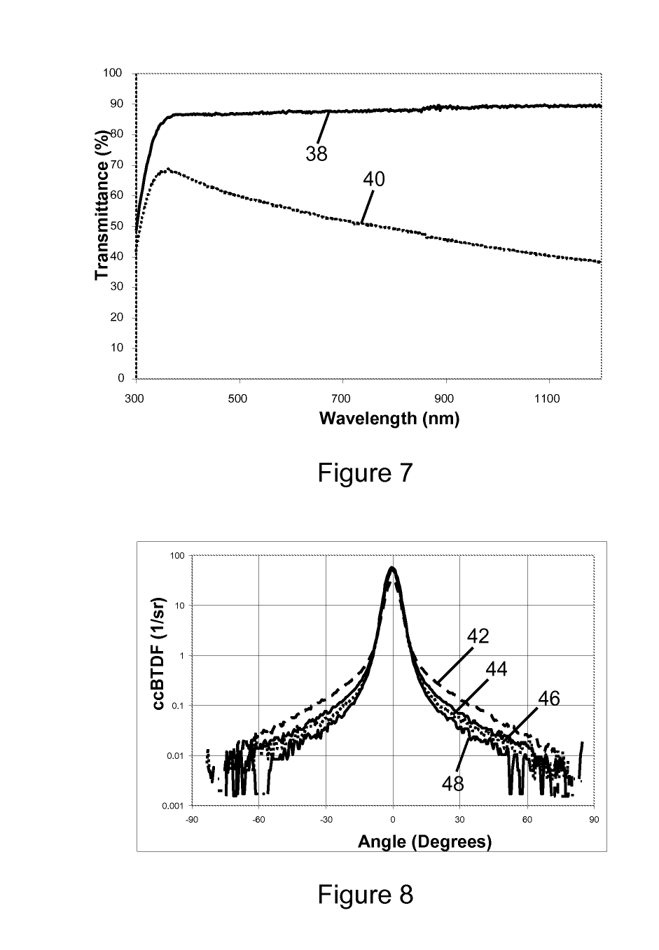

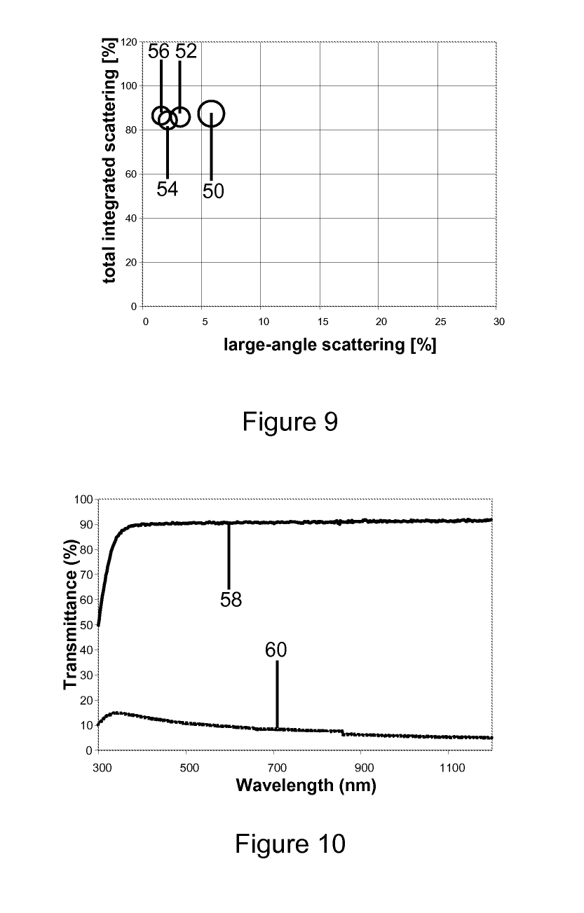

Superstrates were made having surface nucleated surface layers on both top and bottom surfaces. FIG. 7 is a transmittance spectral plot showing total, line 38, and diffuse, line 40, transmittance vs. wavelength of a superstrate having two surface nucleated surface layers having a total average thickness of 80 μm (40 μm average thickness for each surface nucleated surface layer). FIG. 8 is a plot of the angular scattering of an exemplary superstrate. The plot shows scattering function vs. angle for a superstrate having a total average thickness of 80 μm (40 μm average thickness for each surface nucleated surface layer). Lines 42, 44, 46, and 48 show angular scattering at 400 nm, 600 nm, 800 nm, and 1000 nm respectively. FIG. 9 is a plot of total integrated scattering vs. large angle scattering for an exemplary superstrate having a total average thickness of 80 μm (40 μm average thickness for each surface nucleated surface layer). Features 50, 52, 54, and 56 show angular scattering at 400 nm, 600 nm, 800 nm, and 1000 nm, respectively.

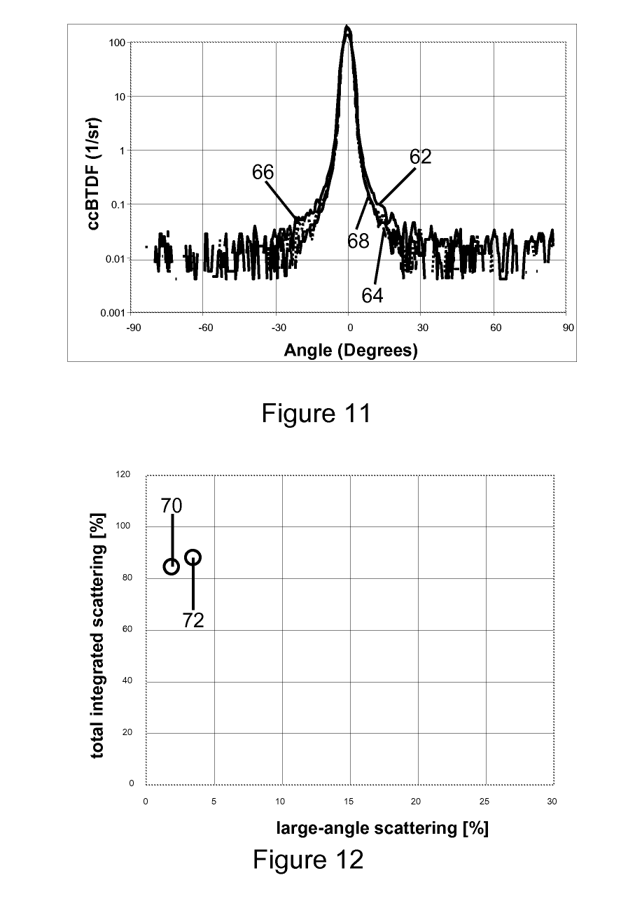

FIG. 10 is a transmittance spectral plot showing total, line 58, and diffuse, line 60, transmittance vs. wavelength of a superstrate having two surface nucleated surface layers having a total average thickness of 30 μm (15 μm average thickness for each surface nucleated surface layer). FIG. 11 is a plot of the angular scattering of an exemplary superstrate. The plot shows scattering function vs. angle for a superstrate having a total average thickness of 30 μm surface nucleated surface layers (15 μm average thickness for each surface nucleated surface layer). Lines 62, 64, 66, and 68 show angular scattering at 400 nm, 600 nm, 800 nm, and 1000 nm respectively. FIG. 12 is a plot of total integrated scattering vs. large angle scattering for an exemplary superstrate having a total average thickness of 80 μm (40 μm average thickness for each surface nucleated surface layer). Features 70 and 72 show angular scattering at 400 nm, and 1000 nm respectively.

As seen from FIGS. 7-9, significant diffuse transmittance (line 38 in FIG. 7), angle scattering dependence (FIG. 8) and large angle scattering were observed (FIG. 9). This is the case where each surface nucleated surface layer is about 40 μm thick. In the case where such layer is about 15 μm in thickness, very low diffuse transmittance (line 60 on FIG. 10), angle scattering dependence (FIG. 11) and scattering at low angles (FIG. 12) are noticeable.

Comparing FIGS. 7 and 10, high diffuse scattering/transmittance causes lower total transmittance (line 38 in FIG. 7 and line 58 in FIG. 10): about 85% (at 350 nm) in FIG. 7 and about 90% (also at 350) on FIG. 10. The optimum conditions are achieved in the case of high diffuse scattering at large angles with still high enough total transmittance.

Existing photovoltaic cell solutions are either very costly or not sufficient, thus improving their efficiency by just few percent could make very significant impact to solar cells market.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A photovoltaic device comprising:
a glass ceramic superstrate comprising a surface nucleated surface layer and having a first surface and a second surface opposite the first surface;
a conductive film adjacent to the glass ceramic substrate; and
an active photovoltaic medium adjacent to the conductive film.

2. The device according to claim 1, wherein the conductive film is disposed on the first surface.

3. The device according to claim 1, wherein the conductive film is disposed on the second surface.

4. The device according to claim 1, wherein the active photovoltaic medium is in physical contact with the conductive film.

5. The device according to claim 1, further comprising a counter electrode in physical contact with the active photovoltaic medium and located on an opposite surface of the active photovoltaic medium as the conductive film.

6. The device according to claim 1, wherein the active photovoltaic medium comprises multiple layers.

7. The device according to claim 1, wherein the active photovoltaic medium comprises cadmium telluride, copper indium gallium diselenide, amorphous silicon, crystalline silicon, microcrystalline silicon, or combinations thereof.

8. The device according to claim 1, wherein the surface nucleated layer has an average thickness of 250 microns or less.

9. The device according to claim 1, comprising two or more surface nucleated surface layers.

10. The device according to claim 9, wherein the glass ceramic superstrate comprises two surface nucleated surface layers, one located at the first surface and another located at the second surface.

11. The device according to claim 10, wherein the surface nucleated layers have a total average thickness 250 microns or less.

12. The device according to claim 1, wherein the glass ceramic superstrate is ion exchanged.

13. The device according to claim 1, wherein the glass ceramic superstrate comprises a lithium alumina silicate composition.

14. The device according to claim 13, wherein the composition is doped with fluorine, chlorine, zinc, or combinations thereof.

15. The device according to claim 13, wherein the composition comprises in mole percent: 60 to 70 SiO₂, 10 to 20 Al₂O₃, and 5 to 15 Li₂O.

16. The device according to claim 15, further comprising greater than 0 to 20 percent RO, wherein R is an alkaline earth metal.

17. The device according to claim 16, wherein R is Ca, Mg, or a combination thereof.

18. The device according to claim 15, further comprising greater than 0 to 10 percent M₂O, wherein M is an alkali metal.

19. The device according to claim 18, wherein M is Na.

20. The device according to claim 1, wherein the superstrate is planar.

21. The device according to claim 1, wherein the conductive film is transparent.

22. The device according to claim 21, wherein the transparent conductive film comprises a textured surface.

23. The device according to claim 1, wherein the average thickness of the superstrate is 3.2 millimeters or less.

24. The device according to claim 23, wherein the average thickness of the superstrate is from 0.5 millimeters to 1.8 millimeters.
